(19) United States
(12) Patent Application Publication
(10) Pub. No.: US 2008/0185625 A1
(43) Pub. Date: Aug. 7, 2008

(54) Source/Drain to Gate Capacitive Switches and Wide Tuning Range Varactors

(75) Inventors: Seong-Mo Yim, Summerfield, NC (US); Kenneth Kyongyup O, Gainesville, FL (US)

Correspondence Address: AKERMAN SENTERFITT, P.O. BOX 3188, WEST PALM BEACH, FL, 33402-3188, US

(73) Assignee: UNIVERSITY OF FLORIDA RESEARCH FOUNDATION, INC., Gainesville, FL (US)

(21) Appl. No.: 11/575,008

(22) PCT Filed: Sep. 12, 2005
(86) PCT No.: PCT/US05/32494

§ 371 Date: Mar. 9, 2007

Related U.S. Application Data
(60) Provisional application No. 60/608,558, filed on Sep. 10, 2004.

(51) Int. Cl. H01L 27/06; H01L 29/93; H03K 17/567

(52) U.S. Cl. 257/300; 438/379; 257/E27.011; 257/E29.344

(57) ABSTRACT

A two-terminal capacitive circuit element 100 includes a MOS transistor including a source 126 and drain 127 separated by a body region 131, and a gate 105 separated from the body 129 by a gate insulator layer 110, and a bypass capacitor 125. The gate node (port2; 115) is AC grounded through the bypass capacitor 125 and the source 126 and drain 127 are tied together (port-1; 120). By toggling the transistor on and off using an appropriate gate to body voltage, the capacitance of the capacitive circuit element 100 between port-1 and port-2 significantly changes.

### FIELD OF THE INVENTION

The invention relates to low loss switches based on capacitive switching, and more specifically to capacitive switches and wide tuning range varactors.

### BACKGROUND

The demand for multiple band and standard radios has increased interest in voltage controlled oscillators with a wide tuning range, as well as tunable amplifiers and mixers. Key components required to implement these tunable blocks are varactors, variable inductors, and variable L-C (VLC) tanks which provide wide tuning ranges. Implementation of variable inductors and LC tanks require low loss capacitive switches.

### SUMMARY

A two-terminal capacitive circuit element comprises a MOS transistor including a source and drain separated by a body region and a gate separated from the body region by a gate insulator layer, and a bypass capacitor, wherein the gate is AC grounded through the bypass capacitor and the source and drain are tied together. By toggling the transistor on and off using an appropriate gate to body voltage, the capacitance of the capacitive circuit element between port-1 and port-2 significantly changes. In one embodiment, the MOS transistor is formed in a well. The MOS transistor can be an NMOS transistor or a PMOS transistor.

One electrode of the bypass capacitor can be provided by the gate of the MOS transistor, or be separate from the MOS transistor. A ratio of a maximum capacitance (Cmax) when the transistor is ON to a minimum capacitance when said transistor is OFF (Cmin) at 1 GHz can be at least 5 for a drawn channel length of at least 1 μm.

A method of providing a variable capacitance comprises the steps of providing a two-terminal capacitive circuit element comprising a MOS transistor including a source and drain separated by a channel region and a gate separated from said channel region by a gate insulator layer, and a bypass capacitor, wherein said gate is AC grounded through the bypass capacitor and the source and drain are tied together, and biasing the gate with a gate voltage toggling between a voltage exceeding a threshold of said MOS transistor and a gate voltage less than the threshold voltage.

### BRIEF DESCRIPTION OF THE DRAWINGS

A fuller understanding of the present invention and the features and benefits thereof will be accomplished upon review of the following detailed description together with the accompanying drawings, in which:

FIG. 1 shows cross sections of an NMOS source/drain to-gate varactor including a bypass capacitor and its equivalent circuit according to an embodiment of the invention in the cutoff (a, b, respectively) and linear mode (c, d, respectively).

FIG. 2 shows a cross sectional view of a capacitive switch according to the invention which utilizes an PMOS transistor to obtain a source/drain to gate (SDG) capacitor structure.

FIG. 3 shows the C_{Vmax}/C_{Vmin} ratio obtained as a function of gate-to-body bias (V_{gb}) for structures with varying drawn channel lengths at varying source/drain-to-body bias (Vⱼ) voltages at 1 GHz.

FIG. 4(a) shows capacitance Cᵥ, (b) resistance Rs, and (c) quality factor (Q) versus gate to body voltage (V_{gb}) at 1 GHz when Vj=0.9V.

FIG. 5 shows Qₒₙ at Cvₘₐₓ, Qₘᵢₙ at Vₜₕ and the capacitance tuning range vs. L_{drawn} at 1 GHz when Vj=0.9V.

FIG. 6(a) shows a variable L-C tank (VLC) circuit schematic including three (3) capacitive switches according to the invention; FIG. 6(b) is a scanned micrograph of the VLC circuit; FIG. 6(c) shows the equivalent circuit looking into port-1 with port-2 grounded for the VLC; FIG. 6(d) shows the measured resistance (Rₚ) for different C_{V} across a frequency range up to about 2.5 GHz; FIG. 6(e) shows the measured susceptance (B) for different C_{V} across a frequency range up to about 2.5 GHz, and (f) shows the Q_{bw} obtained for different C_{V} across a frequency range up to about 3.5 GHz.

### DETAILED DESCRIPTION

A two-port capacitive circuit element includes a MOS transistor including a source and drain separated by a body region, and a gate separated from the body by a gate insulator layer, and a bypass capacitor. The bypass capacitor is preferably separate from the MOS transistor forming the two terminal capacitive circuit element. The gate node (port-2) is AC grounded through the bypass capacitor and the source and drain are tied together (port-1). By toggling the transistor on and off using an appropriate gate to body voltage, the capacitance of the capacitive circuit element between port-1 and port-2 significantly changes. Specifically, in the case that the bypass capacitance is much greater than the gate-to-body capacitance (C_{gb}) the bypass capacitor effectively bypasses the gate to body capacitance (C_{gb}) when the transistor is in the off state producing a low capacitance value for the capacitive circuit element.

The bypass capacitor can be a variety of capacitor types, including a metal-insulator-metal (MIM) capacitor or a metal-oxide-semiconductor (MOS) capacitor. In another embodiment, the bypass capacitor can utilize the gate of the MOS transistor as one terminal with the other terminal being the body (or well in the case of a well process).

The capacitive circuit element can be embodied as a capacitive switch or a varactor. Although described relative to a polysilicon gate NMOS transistor generally having gate oxides, the invention can be embodied using PMOS transistors, and utilize other gate electrode and gate insulator materials. In addition, although the capacitive structures described herein do not use wells, transistors can be formed in wells (e.g. NMOS in a p-well formed in an n-substrate).

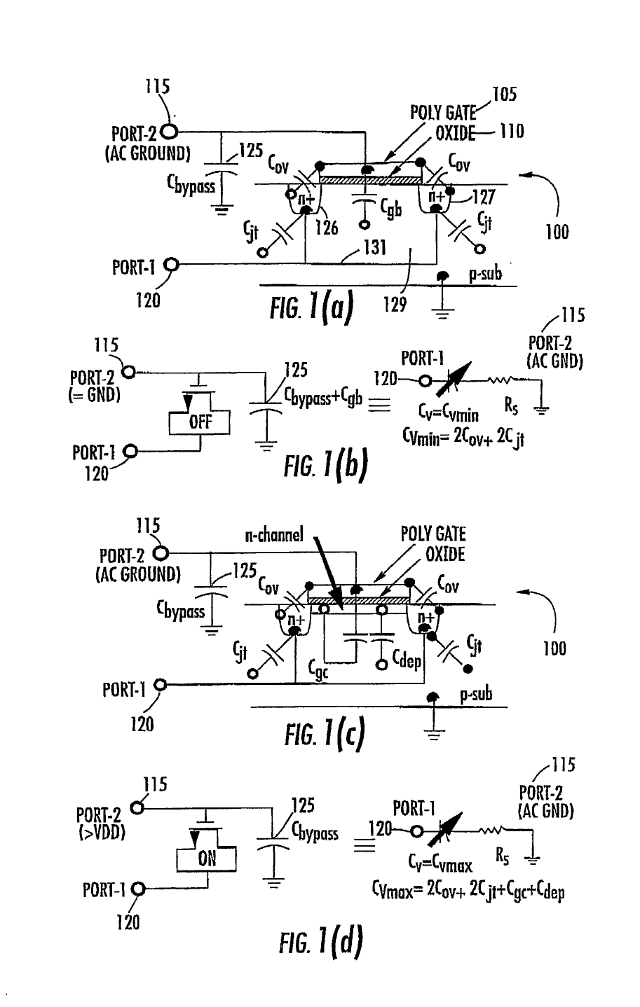

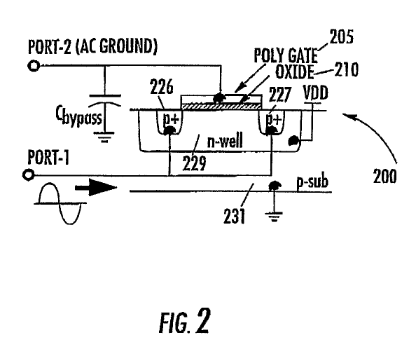

A cross sectional view of a capacitive switch 100 according to the invention shown in FIG. 1(a) which utilizes an NMOS transistor to obtain a source/drain to gate (SDG) capacitor structure. Capacitive switch 100 includes gate electrode (shown as a polysilicon gate) 105, gate insulator 110 (shown as a gate oxide), n+ source 126 and drain 127 diffused into body (p-substrate) 129. Unlike a conventional MOS varactor or capacitive switch, the gate node (port-2; 115) is AC grounded using a bypass capacitor 125 (C_{bypass}) and is also connected to a DC control voltage. The n+ source 126 and drain 127 terminals are tied together using an electrically conductive layer, such as a metal layer 131, and are connected to an AC node at port-1 (120). Connecting the source 126 and drain 127 together allows the capacitive switch 100 to operate between cut-off (OFF) when the DC control voltage is <Vₜₕ (such as when grounded), and the linear (ON) region which forms an n-channel when the DC control voltage is >Vₜₕ as shown in FIGS. 1 (a) and (c), respectively.

When the NMOS transistor is in the cut-off (OFF) region, the equivalent circuit model for capacitive switch 100 is shown in FIG. 1(b). In this bias state, the gate-to-body capacitance (C_{gb}) is bypassed by the much larger C_{bypass} and is effectively excluded f r o m the capacitance of the capacitive switch 100 measured between port-1 and port-2, denoted as (Cᵥ). As a result, C_{Vmin} seen from port-1 (120) is effectively equal to 2Cₒᵥ (gate-to-source/drain overlap capacitances) plus 2Cⱼₜ (source/drain-to-body capacitances). Rs shown in FIG. 1(b) represents the series resistance from gate-to-source/drain resistance and source/drain-to-body resistance.

The equivalent circuit model for capacitive switch 100 measured between port-1 (120) and port-2 (115) when the NMOS is in the linear (ON) region is shown in FIG. 1(d). The surface of the p-body under the gate is inverted (n-type). As a result, Cᵥ seen from port-1 (120) is equal to the sum of 2Cₒᵥ, 2Cⱼₜ, the gate-to-channel capacitance (C_{gc}), and channel to body capacitance (C_{dep}). The resulting total capacitance is denoted as the maximum capacitance (Cᵥₘₐₓ).

However, in an alternate embodiment, port-2 (115) of capacitive switch 100 is not AC grounded by sufficiently lowering the value Of C_{bypass}. In this embodiment, the overlap capacitance (2Cₒᵥ) is in series with C_{gb}, and the capacitance C_{Vmin} seen from port-1 (120) can be even lower. Thus, in this arrangement, the capacitance ratio (C_{Vmax}/ C_{Vmin}) can further be improved.

C_{gc} and C_{dep} can be made much larger than Cₒᵥ and Cⱼₜ by making the channel length longer to increase the Cᵥₘₐₓ/C_{Vmin} ratio. However, increased channel length increases the channel resistance (R_{ch}). Exemplary layouts of various capacitive switches/varactors with W/L_{drawn} ratios of 64 μm/0.18 μm, 32 μm/0.36 μm, 16 μm/0.72 μm, 8 μm/1.44 μm, and 4 μm/2.88 μm have been fabricated and studied. Compared to a MOS transistor switch which adds R_{ch} in series, because the source and drain are tied together in capacitive switch 100 shown in FIG. 1, a capacitive switch according to the invention with the same channel length adds series resistance of only about R_{ch}/12. This provides capacitive switches having lower loss, and thus higher Q, as compared to conventional MOS transistor switches.

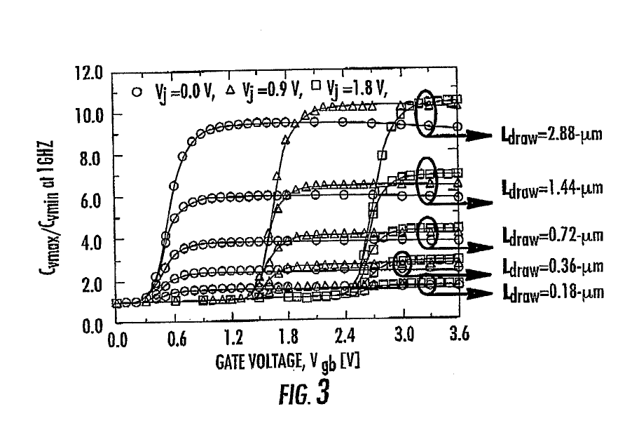

As noted above, capacitive elements according to the invention can also be implemented using PMOS transistors. FIG. 2 shows a cross sectional view of a capacitive switch 200 according to the invention which utilizes an PMOS transistor to obtain a source/drain to gate (SDG) capacitor structure. Capacitive switch 200 includes gate electrode (shown as a polysilicon gate) 205, gate insulator 210 (shown as a gate oxide), p+ source 226 and drain 227 diffused into an n-well 229 which is diffused into p-substrate) 231. A potential advantage of this implementation is that since the structure can be placed in an isolated well, it should pick up less noise injected into the substrate by other nearby circuitry. A potential disadvantage is that the inversion layer resistance may be higher. However, in CMOS processes which provide a deep n-well, the high resistance can be bypassed using NMOS transistors in isolated p-wells.

FIG. 3 shows the measured C_{Vmax}/C_{Vmin} ratio as function of gate-to-body bias (V_{gb}) for capacitive circuit elements according to the invention having varying drawn channel lengths at various source/drain-to-body bias (Vⱼ) voltages. The C_{Vmax}/C_{Vmin} ratio increases for increasing L_{drawn} and can be greater than 10. As Vⱼ increases, Cⱼₜ decreases and Cₒᵥ slightly decreases because the effective gate-to-drain/source overlap is reduced. This decreases C_{Vmin} and C_{Vmax} and slightly increases the C_{Vmin}/C_{Vmax} ratio and tuning range.

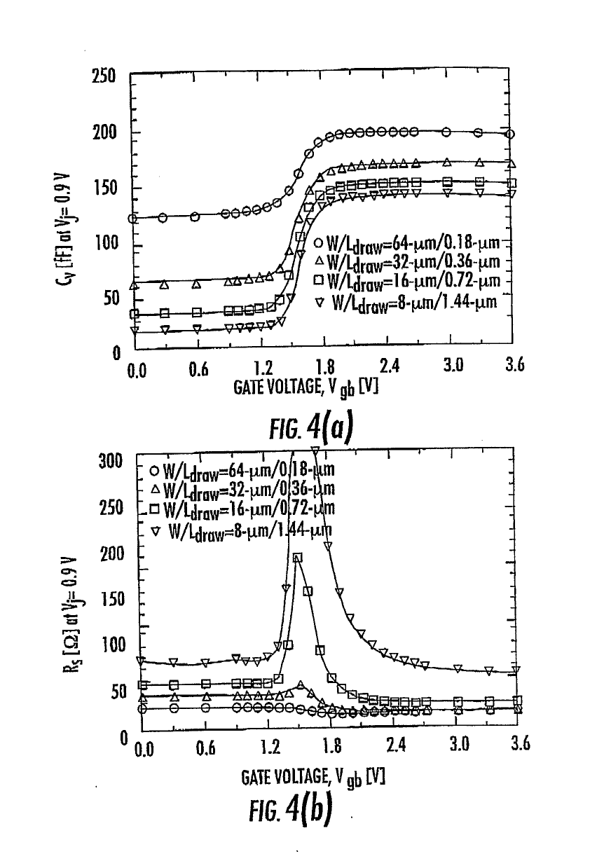

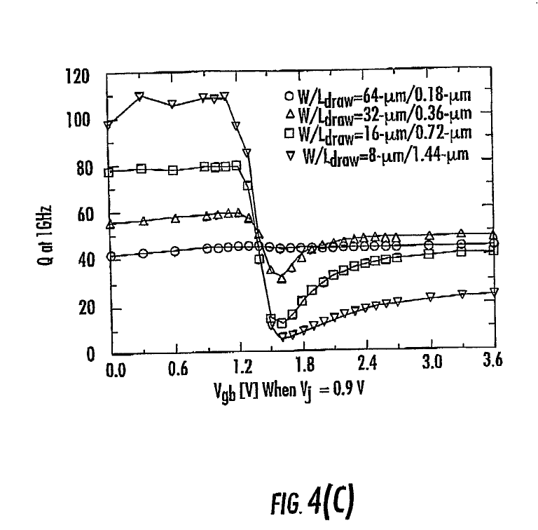

When the MOS structure is in the linear region, the series resistance (Rₛ) is mainly due to R_{ch} and increases as the drawn channel length (L_{drawn}) increases as shown in FIG. 4(b). Because of this, measured Qₒₙ is not as high as that of accumulation mode MOS varactors, and decreases as L_{drawn} increases as shown in FIG. 4(c). There is thus a trade-off between a wide tuning range and a high quality (Q) factor.

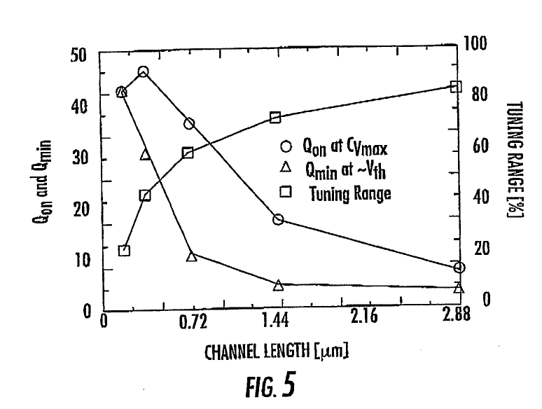

FIG. 5 shows the measured Qₒₙ at Cvₘₐₓ, Qₘᵢₙ at Vₜₕ and capacitance tuning range vs. L_{drawn} at 1 GHz when Vj=0.9V. The impact of the lower Q can be reduced because when the MOS transistor is on, the varactor is generally used to create an L-C circuit resonating at a lower frequency and Q is inversely proportional to the frequency (ω). The minimum Q (Qₘᵢₙ) occurs when port-2 is biased around the threshold voltage as shown in FIG. 4(c) and FIG. 5, where the channel resistance is large. Since when used as a switch, the inventive capacitive structure does not operate around the threshold voltage, Qₘᵢₙ is not an issue. However, channel resistance (Rₛ) can become a factor when the inventive capacitive structure is used as a varactor.

### EXAMPLES

The present invention is further illustrated by the following specific Examples, which should not be construed as limiting the scope or content of the invention in any way.

Capacitive structures according to the invention were designed, fabricated using a 0.18-μm standard CMOS technology, and then tested. The measured tuning ranges of the capacitive structures according to the invention given below in Table I are wide.

| W/L_{draw} | C_{Vmax} | C_{Vmin} | Tuning | C_{Vmax} | Qₒₙ at | Qₘᵢₙ at | Qₒₙ at | Q_{off} at |
|---|---|---|---|---|---|---|---|---|
| [μm/μm] | [fF] | [fF] | Range | C_{Vmin} | C_{Vmax} | V_{gs} = −Vₜₕ | V_{gs} = 1.8 V | V_{gs} = 0 V |
| 64/0.18 | 178.79 | 110.5 | ±23.58% | 1.617 | 51.153 | 51.288 | 50.816 | ~50 |
| 32/0.36 | 156.36 | 58.41 | ±45.60% | 2.677 | 53.193 | 36.270 | 53.481 | ~70 |
| 16/0.72 | 141.24 | 33.91 | ±61.27% | 4.164 | 38.487 | 11.319 | 39.419 | ~95 |
| 8/1.44 | 131.18 | 19.37 | ±74.30% | 6.772 | 15.726 | 4.147 | 16.579 | ~110 |
| 4/2.88 | 125.10 | 12.13 | ±82.32% | 10.320 | 5.255 | 2.683 | 5.255 | ~300 |

Specifically, the tuning range increased from ±23.6% to ±45.6% as L_{drawn} was increased from 0.18-μm and 0.36-μm. The quality factor (Qₒₙ) when the gate-to source voltage (V_{gs}) was 1.8 V was about 50 at 1 GHz, and the minimum quality factor (Qₘᵢₙ) when V_{gs} was near Vₜₕ was found to decrease from about 50 to 36.4. When L_{drawn} was increased further to 0.54 μm, varactors according to the invention should have about a ±53% tuning range and Qₘᵢₙ of near 20 at 1 GHz. Such a Qmin is sufficiently high for the structure to generally be used as a varactor. A ±53% tuning range is about 75% higher as compared to previously reported two terminal varactors and comparable to those of three terminal varactors.

When L_{drawn} is between 0.72-μm and 1.44-μm, the structure can be used as a capacitive switch to avoid the Qₘᵢₙ problem. As L_{drawn} was increased in this range, the tuning range increased from ±61.2% to ±74.3%, and the C_{Vmax} to C_{Vmin} ratio increases from 4.2 to 6.8. Qₒₙ at 1 GHz decreases from 38.4 to 15.7.

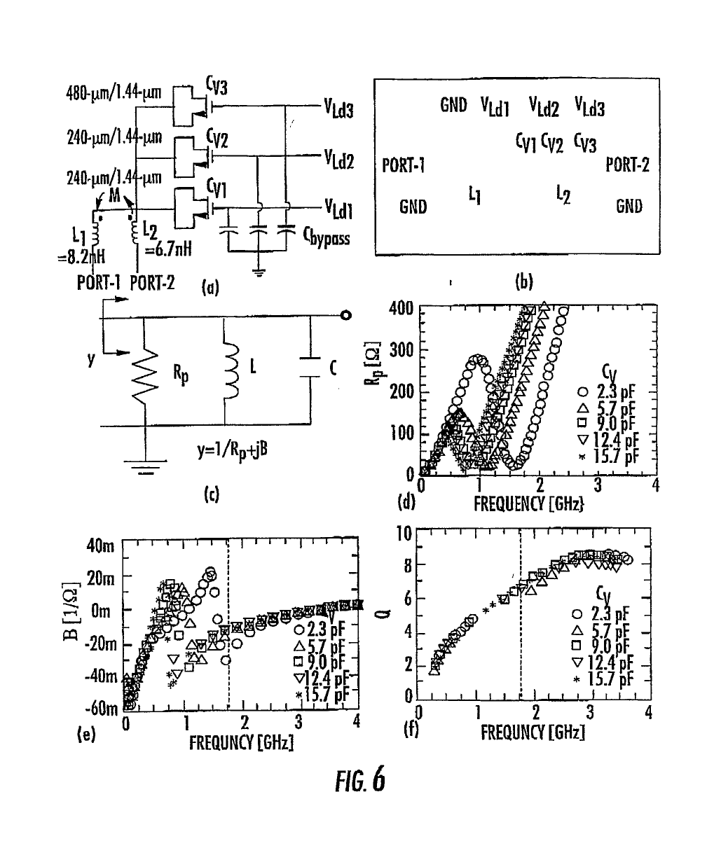

The invention was applied to a circuit arrangement referred to as a variable L-C (VLC) tank. FIGS. 6(a) shows a VLC tank schematic including three (3) capacitive switches C_{V1}-C_{V3} according to the invention providing a C_{Vmax}/C_{Vmin} ratio of 6.8, while FIG. 6(b) is a scanned micrograph of the VLC circuit. The capacitive switches each include a separate control input (V_{Ld1}, V_{Ld2}, or V_{Ld3}). The VLC tank can be used as part of a tunable output matching network for a low noise amplifier (LNA), such as an LNA that can be tuned between 0.7 and 2.1 GHz for multi-band operation.

FIG. 6(c) shows a simplified equivalent circuit looking into port-1 with port-2 grounded for the VLC. FIG. 6(d) shows the measured resistance (Rₚ) for different Cᵥ across a frequency range up to about 2.5 GHz, while FIG. 6(e) shows the measured susceptance (B) for different Cᵥ across a frequency range up to about 2.5 GHz. Between 0.7 and 2.5 GHz the susceptance (B) can be made negative or the VLC can be made to behave as an inductor. At a given frequency, B increases or effective inductance becomes smaller as the capacitance is increased by turning on more capacitive switches (moving up on the dotted line in FIG. 6(e)). FIG. 6(f) shows Q_{bw} obtained for different Cᵥ by switching V_{Ld1}, V_{Ld2}, and V_{Ld3} on and off between 0 V and 1.8 V across a frequency range up to about 3.5 GHz. The Q-factors of structures generally ranged between 4.5 and 8, which is suitable for an LNA output matching network.

It is to be understood that while the invention has been described in conjunction with the preferred specific embodiments thereof, that the foregoing description as well as the examples which follow are intended to illustrate and not limit the scope of the invention. Other aspects, advantages and modifications within the scope of the invention will be apparent to those skilled in the art to which the invention pertains.

1. A two-terminal capacitive circuit element, comprising:
a MOS transistor including a source and drain separated by a body region and a gate separated from said body region by a gate insulator layer, and
a bypass capacitor, wherein said gate is AC grounded through said bypass capacitor and said source and drain are tied together.

2. The capacitive circuit element of claim 1, wherein said MOS transistor is formed in a well.

3. The capacitive circuit element of claim 1, wherein said MOS transistor is an NMOS transistor.

4. The circuit element of claim 1, wherein said MOS transistor is a PMOS transistor.

5. The circuit element of claim 1, wherein one electrode of said bypass capacitor is provided by said gate.

6. The circuit element of claim 1, wherein a ratio of a maximum capacitance (Cₘₐₓ) when said transistor is ON to a minimum capacitance when said transistor is OFF (Cₘᵢₙ) at 1 GHz is at least 5 for a drawn channel length of at least 1 μm.

7. A method of providing a variable capacitance, comprising the steps of:
providing a two-terminal capacitive circuit element comprising a MOS transistor including a source and drain separated by a channel region and a gate separated from said channel region by a gate insulator layer, and a bypass capacitor, wherein said gate is AC grounded through said bypass capacitor and said source and drain are tied together, and
biasing said gate with a gate voltage toggling between a voltage exceeding a threshold of said MOS transistor and a gate voltage less than said threshold voltage.
